(19) United States
(12) Patent Application Publication
(10) Pub. No.: US 2025/0329661 A1
(43) Pub. Date: Oct. 23, 2025

(54) METHOD OF MANUFACTURING SEMICONDUCTOR DEVICE AND PRODUCT HISTORY MANAGEMENT METHOD FOR SEMICONDUCTOR DEVICE

(71) Applicant: Renesas Electronics Corporation, Tokyo (JP)

(72) Inventors: Tsuyoshi KANAO, Tokyo (JP); Junpei NONAKA, Tokyo (JP)

(21) Appl. No.: 19/172,756

(22) Filed: Apr. 8, 2025

(30) Foreign Application Priority Data
Apr. 18, 2024 (JP) 2024-067616

(51) Int. Cl. H01L 23/544; H01L 21/56; H01L 21/66

(52) U.S. Cl. CPC H01L 23/544; H01L 21/561; H01L 22/12; H01L 22/14; H01L 2223/54433

(57) ABSTRACT

The technique capable of preventing cost increase and performing traceability of a semiconductor device with higher accuracy is demanded. In each of a plurality of chip regions, a multilayer wiring layer having a plurality of metal films in the uppermost-layer wiring layer is formed. In each of the plurality of chip regions, a surface morphology image of a specific area of the metal films is obtained. A wafer identification number, positional information of each of the plurality of chip regions, positional information of the specific area of each of the chip regions, and the surface morphology image for each of the plurality of chip regions are associated with one another, and these pieces of information are stored in the storage device.

### CROSS-REFERENCE TO RELATED APPLICATIONS

The disclosure of Japanese Patent Application No. 2024-067616 filed on Apr. 18, 2024 including the specification, drawings and abstract is incorporated herein by reference in its entirety.

### BACKGROUND

The present invention relates to a method of manufacturing a semiconductor device and a product history management method for a semiconductor device.

In a case in which a defect is detected after manufacture of a semiconductor device, it is required to identify the cause of the defect at an early stage and to perform feedback to a manufacturing process of the relevant semiconductor device. For such cases, traceability of a semiconductor device having determined to be defective is effective. More specifically, it is effective to clarify which lot number and wafer identification number to which the wafer belonging to was used to manufacture the semiconductor device determined to be defective, and clarify at which position in the wafer where such a semiconductor device has been manufactured.

There are disclosed techniques listed below.

### [Patent Document 1] Japanese Unexamined Patent Application Publication No. 2007-165389

For example, Patent Document 1 discloses that, at four corners of a semiconductor chip, an image of a dicing mark on a side surface of a wafer and an image of a contact mark on a front surface of a pad electrode formed at a time of a probe inspection are stored in a storage device. As for a semiconductor chip determined to be defective, similar images are obtained, and these images are used to match the images stored in the storage device, so that a wafer identification number and a location in a wafer in which the semiconductor chip determined to be defective has been manufactured is identified.

### SUMMARY

In general, at the stage of the front-end process of manufacturing semiconductors, an identification symbol is allocated to a wafer. However, an identification symbol is not allocated to a semiconductor chip obtained by singulating a wafer. If an identification symbol is allocated to all of semiconductor chips, traceability is enabled. However, such a method leads to cost increase.

A semiconductor chip obtained by singulating a wafer is packaged through the back-end process of manufacturing of semiconductors, and a semiconductor device is manufactured. In the course of this process, on a front surface of a pad electrode, a member for external connection such as a bonding wire or a bump electrode is formed. In addition, the semiconductor chip is covered with a sealing resin. In order to perform traceability of a semiconductor device determined to be defective, even after a sealing resin is opened and the member for external connection is removed, information for leading to identification of the semiconductor chip is required to be obtained with higher accuracy.

More specifically, a technique of achieving suppression of cost increase and allowing traceability of a semiconductor device to be performed with higher accuracy is demanded. In addition, a technique of allowing a cause of a defect of the semiconductor device to be identified at an early stage and enabling feedback to a method of manufacturing a semiconductor device at an early stage to be performed is demanded. With these techniques, after the feedback is performed, it is possible to supply a semiconductor device with higher reliability, improve a manufacturing yield, and prevent distribution of defective products to a market.

Other objects and novel characteristics of the present invention will be apparent from the description of the present specification and the accompanying drawings.

The typical ones of the embodiments disclosed in the present application will be briefly described as follows.

A method of manufacturing a semiconductor device according to one embodiment includes (a) allocating a wafer identification number to a wafer including a semiconductor material, (b) demarcating the wafer into a plurality of chip regions positioned in a matrix to generate a wafer map, (c) forming a semiconductor element in each of the plurality of chip regions, (d) forming a multilayer wiring layer positioned on an upper side of the semiconductor element in each of the plurality of chip regions and having a plurality of metal films in an uppermost-layer wiring layer thereof, (e) obtaining a first surface morphology image of a specific area of the metal films in each of the plurality of chip regions, and (f) associating the wafer identification number, positional information of each of the plurality of chip regions, positional information of the specific area in each of the chip regions, and the first surface morphology image for each of the plurality of chip regions with one another, and storing these pieces of information in the storage device.

A product history management method for a semiconductor device according to one embodiment includes (a) allocating a wafer identification number to a wafer including a semiconductor material, (b) demarcating the wafer into a plurality of chip regions positioned in a matrix to generate a wafer map, (c) forming a semiconductor element in each of the plurality of chip regions, (d) forming a plurality of metal films in an uppermost-layer wiring layer of a multilayer wiring layer positioned on an upper side of the semiconductor element in each of the plurality of chip regions, (e) obtaining a first surface morphology image of a specific area of the metal films in each of the plurality of chip regions, (f) associating the wafer identification number, positional information of each of the plurality of chip regions, positional information of the specific area in each of the chip regions, and the first surface morphology image for each of the plurality of chip regions with one another, and storing these pieces of information in the storage device, (g) singulating the wafer into the plurality of chip regions, thereby obtaining a plurality of semiconductor chips, (h) sealing each of the plurality of semiconductor chips with a sealing resin, thereby forming a plurality of first semiconductor devices, (i) obtaining a second semiconductor device which has been determined to be defective, (j) opening the sealing resin of the second semiconductor device, and obtaining a second surface morphology image of a portion corresponding to the specific area of the metal films provided in the second semiconductor device, and (k) matching the second surface morphology image with the first surface morphology image for each of the plurality of chip regions stored in the storage device, thereby identifying the wafer identification number of the wafer in which the second semiconductor device has been manufactured and a position of the chip region in which the second semiconductor device has been manufactured.

According to one embodiment, it is possible to prevent cost increase and perform traceability of the semiconductor device with higher accuracy. In addition, it is possible to identify a cause of a defect of a semiconductor device at an early stage and to perform feedback to the method of manufacturing the semiconductor device.

### BRIEF DESCRIPTION OF THE DRAWINGS

FIG. 1 is a flow chart indicating a method of manufacturing a semiconductor device and a product history management method for a semiconductor device according to a first embodiment.

FIG. 2 is a plan view illustrating a wafer map according to the first embodiment.

FIG. 3 is a plan view illustrating a chip region according to the first embodiment.

FIG. 4 is a schematic view illustrating the manner in which data is stored in a storage device in the first embodiment.

FIG. 5 is a schematic view illustrating the manner in which data is stored in the storage device in the first embodiment.

FIG. 6 is a cross-sectional view illustrating the method of manufacturing a semiconductor device according to the first embodiment.

FIG. 7 is a cross-sectional view illustrating a manufacturing process subsequent to FIG. 6.

FIG. 8 is a cross-sectional view illustrating a manufacturing process subsequent to FIG. 7.

FIG. 9 is a cross-sectional view illustrating a manufacturing process subsequent to FIG. 8.

FIG. 10 is a cross-sectional view illustrating a manufacturing process subsequent to FIG. 9.

FIG. 11 is a schematic view illustrating a manufacturing process subsequent to FIG. 10 and a schematic view illustrating a product history management process of the semiconductor device thereafter.

FIG. 12 is a plan view illustrating the product history management process subsequent to FIG. 11.

FIG. 13 is a plan view illustrating the product history management process subsequent to FIG. 12.

FIG. 14 is a schematic view illustrating a method of matching a surface morphology image in a second embodiment.

FIG. 15 is a plan view illustrating shapes of patterns of a metal film in a third embodiment.

FIG. 16 is a plan view illustrating a chip region in a fourth embodiment.

### DETAILED DESCRIPTION

Hereinafter, embodiments will be described in detail with reference to the accompanying drawings. In all the drawings for explaining the embodiments, the same symbol is assigned to the component having the same function, and the repeated explanation thereof is omitted. In the following embodiments, the explanation of the same or similar portion is not repeated unless otherwise particularly necessary.

In addition, direction, a Y direction, and a Z direction described in the present application intersect with and are orthogonal to each other. In the present application, the Z direction is used as a vertical direction, a height direction, or a thickness direction of a structural element for description. In addition, a “plan view,” “in a plan view,” or similar expressions used in the present application mean that a plane formed by the X direction and the Y direction as a “plane,” and that this “plane” is viewed from the Z direction.

### FIRST EMBODIMENT

### Method of Manufacturing Semiconductor Device and Product History Management Method for Semiconductor Device

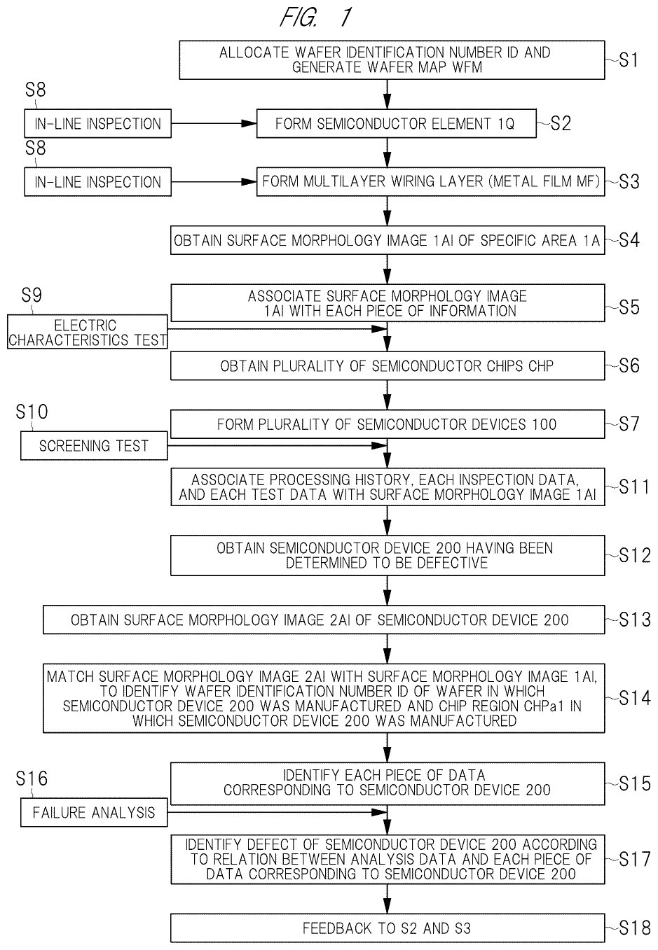

Hereinafter, a method of manufacturing a semiconductor device 100 and a product history management method for the semiconductor device 100 according to a first embodiment will be described with reference to FIG. 1. The product history management method for the semiconductor device 100 includes steps S1 to S18 indicated in FIG. 1. The method of manufacturing the semiconductor device 100 is part of the product history management method for the semiconductor device 100 and includes steps S1 to S13.

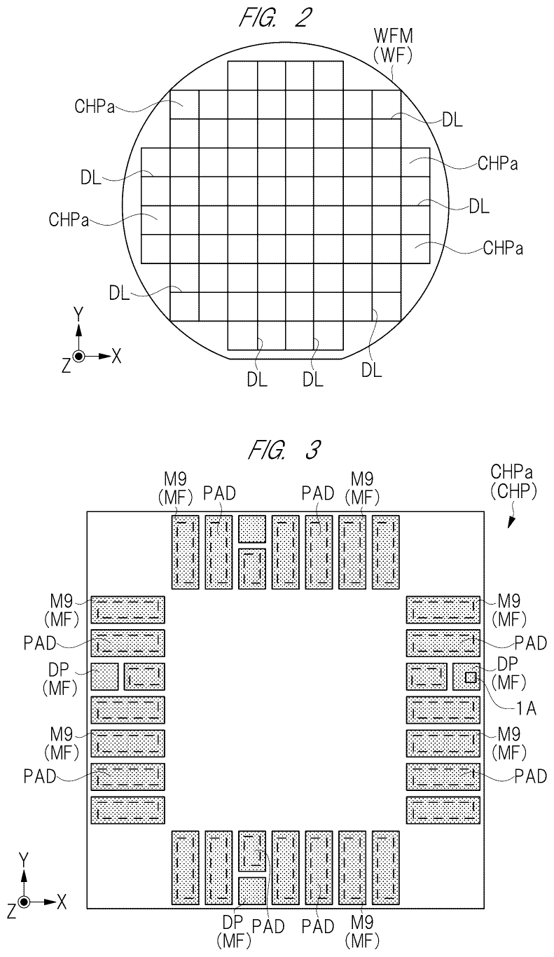

In addition, the description of steps S1 to S18 is given by using FIGS. 2 to 13, as needed.

In step S1, first, a wafer WF is prepared, and as illustrated in FIG. 4, a wafer identification number ID is allocated to part of the wafer WF. Then, as illustrated in FIG. 2, the wafer WF is demarcated into a plurality of chip regions CHPa which are arranged in a matrix, and a wafer map WFM is generated. The plurality of chip regions CHPa are demarcated by a grid of dicing lines DL. The plurality of chip regions CHPa are divided into individual pieces along the dicing lines DL, so that a plurality of semiconductor chips CHP are obtained.

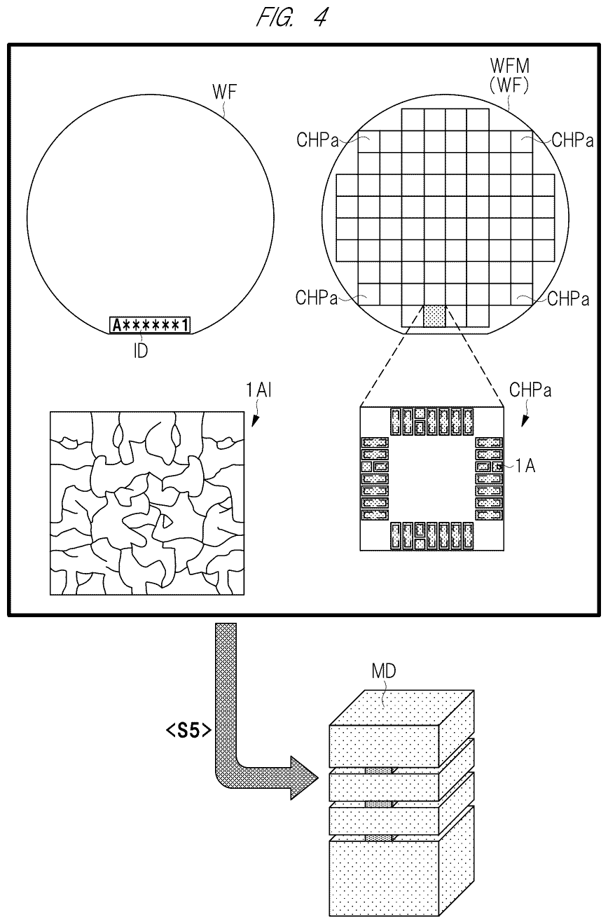

FIG. 3 is a plan view illustrating details of the chip regions CHPa (semiconductor chips CHP). The chip regions CHPa each have a multilayer wiring layer and each have a plurality of metal films MF in the uppermost-layer wiring layer of the multilayer wiring layer. The plurality of metal films MF include a plurality of wires M9 and a plurality of dummy patterns DP.

Although not illustrated here, the plurality of wires M9 and the plurality of dummy patterns DP are covered with a protective film PF. An opening is provided at part of the protective film PF. Portions which are exposed at the opening of the plurality of wires M9 serve as pad electrodes PAD. Portions surrounded by broken lines illustrated in FIG. 3 are the pad electrodes PAD. The member for external connection such as the bonding wire or the bump electrode is connected on the pad electrode PAD, so that the semiconductor chip CHP is electrically connected to another semiconductor chip, a wiring substrate, or the like.

The plurality of wires M9 are electrically connected to a semiconductor element 1Q which will be described later. The plurality of dummy patterns DP are not electrically connected to the semiconductor element 10 and are in an electrically floating state. In addition, the plurality of dummy patterns DP are not connected with the member for external connection.

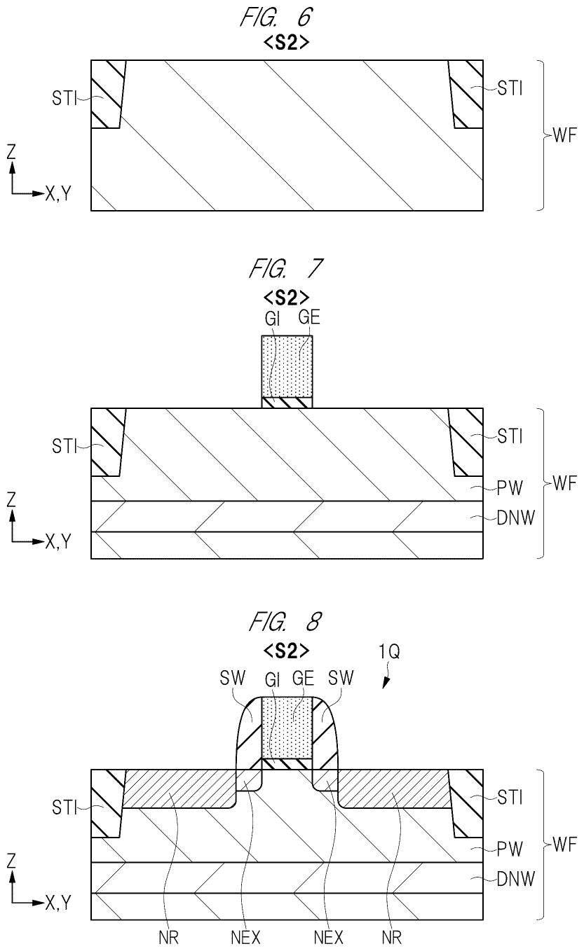

In step S2, in each of the plurality of chip regions CHPa, a semiconductor element 10 is formed. With reference to FIGS. 6 to 8, description of manufacturing processes for forming the semiconductor element 1Q will be given below. Here, as the semiconductor element 10, an n-type MOSFET (Metal Oxide Semiconductor Field Effect Transistor) will be illustrated. Note that the n-type MOSFET is by way of example of the semiconductor element 10, and in the wafer WF, a plurality of other semiconductor elements such as a p-type MOSFET, a capacitive element, and a resistive element are formed, although description thereof will be omitted here.

As illustrated in FIG. 6, first, a wafer WF including a p-type monocrystalline silicon substrate is prepared. The wafer WF may be a layered structure including the monocrystalline silicon substrate described above and a silicon layer formed on the monocrystalline silicon substrate by the epitaxial growth.

Next, on the wafer WF, for example, by a film forming treatment through the CVD (Chemical Vapor Deposition), an insulating film such as a silicon nitride film is formed. Then, the insulating film is patterned, thereby forming a hard mask.

Subsequently, with the hard mask as a mask, a trench is formed in the wafer WF. Then, in such a manner as to bury the interior of the trench, an insulating film such as a silicon oxide film is formed on the wafer WF, by a film forming treatment through the CVD, for example. Subsequently, by a polishing process such as the CMP (Chemical Mechanical Polishing), the insulating film that is positioned outside the trench is removed. Next, by wet etching, the hard mask is removed. In the manner described above, a plurality of element isolation portions STI which define an active region are formed in the wafer WF.

As illustrated in FIG. 7, first, in the wafer WF, by photolithography and ion implantation, a well region DNW which is an n-type impurity region is formed. Next, by photolithography and ion implantation, a well region PW which is a p-type impurity region is formed in the well region DNW.

Next, a gate insulating film GI including an oxide silicon film is formed on the wafer WF, by a thermal oxidation treatment. Subsequently, for example, by a film forming treatment through the CVD, for example, n-type polycrystalline silicon film is formed on the gate insulating film GI. Then, the polycrystalline silicon film is patterned, resulting in formation of a gate electrode GE.

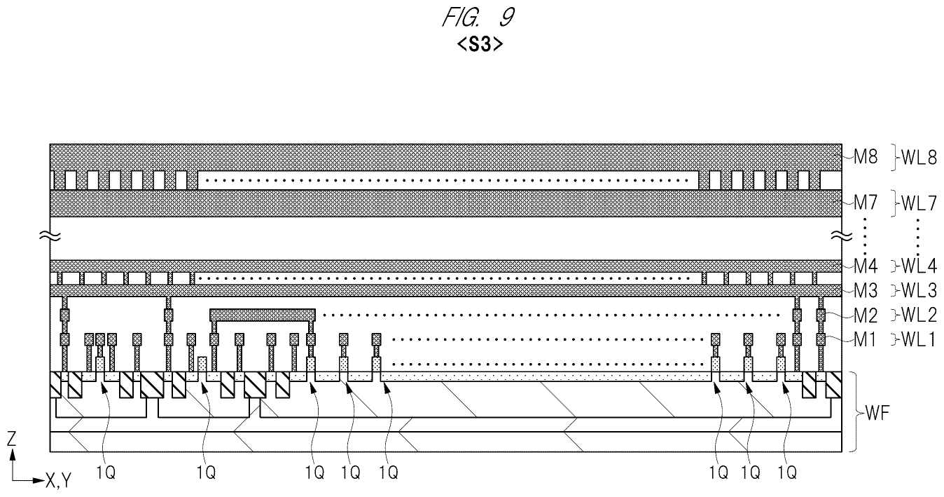

As illustrated in FIG. 8, first, in the well region PW which is exposed from the gate electrode GE, by photolithography and ion implantation, an extension region NEX which is an n-type impurity region is formed.

Next, in such a manner as to cover the gate electrode GE, for example, by a film forming treatment through the CVD, for example, an oxide silicon film and a silicon nitride film are sequentially formed. Subsequently, by anisotropic etching, the oxide silicon film and the silicon nitride film are processed. As such, sidewall spacers SW are formed on side surfaces of the gate electrode GE.

Next, in the well region PW exposed from the sidewall spacers SW, by photolithography and ion implantation, a high concentration diffusion region NR which is an n-type impurity region is formed. The high concentration diffusion region NR has an impurity concentration higher than that of the extension region NEX.

In this manner described above, an n-type MOSFET is formed as a semiconductor element 10. The n-type MOSFET has the gate insulating film GI, the gate electrode GE, the sidewall spacer SW, the extension region NEX, and the high concentration diffusion region NR. The extension region NEX and the high concentration diffusion region NR constitute a source region or a drain region of the n-type MOSFET. A portion of the well region PW which is interposed between the two extension regions NEX and positioned below the gate electrode GE constitutes a channel region of the n-type MOSFET.

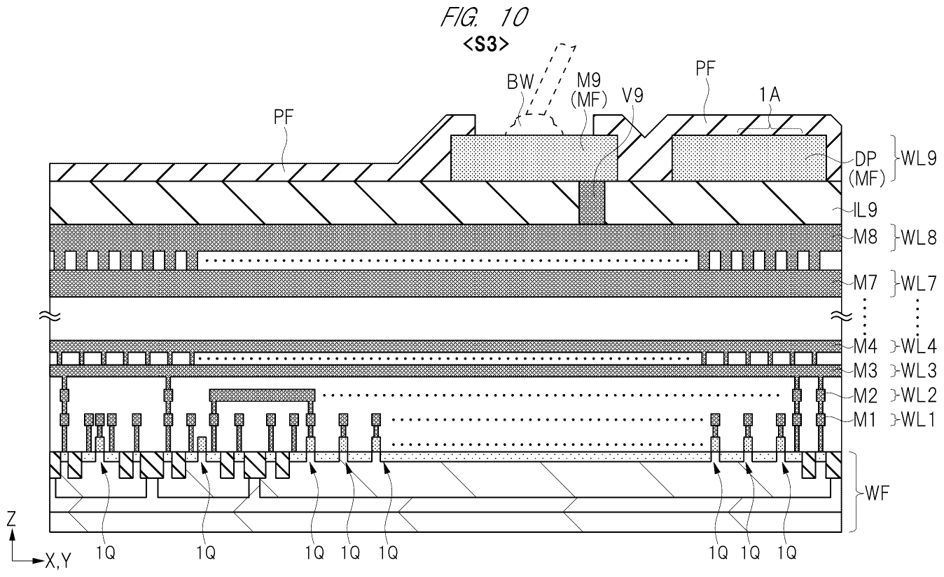

In step S3, a multilayer wiring layer that is positioned above the semiconductor element 10 is formed in each of the plurality of chip regions CHPa. With reference to FIG. 9 and FIG. 10, manufacturing processes for forming the multilayer wiring layer will be described below.

The multilayer wiring layer includes, for example, the first wiring layer WL1 to the ninth wiring layer WL9. Here, although the ninth wiring layer WL9 is the uppermost-layer wiring layer of the multilayer wiring layer, the number of layers in the wiring layer is merely one example and can be changed as needed.

As illustrated in FIG. 9, a plurality of wires M1 to M8 are formed in the first wiring layer WL1 to the eighth wiring layer WL8, respectively. The plurality of wires M1 to M8 can be formed by the existing damascene method or the dual damascene method. Each of the plurality of wires M1 to M8 is formed on a barrier metal film including a tantalum film and a tantalum nitride film, and a copper film which is formed on the barrier metal film and which has a thickness greater than that of the barrier metal film, for example.

As illustrated in FIG. 10, first, for example, by the film forming treatment through the CVD, an interlayer insulating film IL9 is formed on the eighth wiring layer WL8. The interlayer insulating film IL9 includes, for example, an oxide silicon film. Subsequently, by photolithography and anisotropic etching, a contact hole is formed selectively in the interlayer insulating film IL9. Then, in such a manner as to bury the interior of the contact hole, by the film forming treatment through sputtering or the CVD, a titanium nitride film and a tungsten film are sequentially formed on the interlayer insulating film IL9. Next, by a polishing treatment through the CMP, by removing the titanium nitride film and the tungsten film positioned outside the contact hole, a via V9 is formed in the interior of the contact hole.

Next, by the film forming treatment through sputtering or the CVD, a film containing aluminum as a main material is formed on the interlayer insulating film IL9. More specifically, the film containing aluminum as the main material is a layered film including, for example, a barrier metal film including a titanium tungsten film, and an aluminum alloy film which is formed on the barrier metal film and to which copper or silicon is added, for example.

Next, by photolithography and anisotropic etching, the film containing aluminum as the main material is subjected to patterning. As such, in the ninth wiring layer WL9, a plurality of metal films MF are formed. As illustrated in FIG. 3, the plurality of metal films MF include the plurality of wires M9 and the plurality of dummy patterns DP.

Next, in such a manner as to cover the plurality of wires M9 and the plurality of dummy patterns DP, for example, by the film forming treatment through the CVD, a protective film PF is formed on the interlayer insulating film IL9. The protective film PF is, for example, an oxide silicon film, a silicon oxynitride film, or a silicon nitride film, or is a layered film obtained by having these films layered on top of another, as appropriate. Next, by photolithography and anisotropic etching, by subjecting a portion of the protective film PF positioned on the wire M9 to patterning, a region of the wire M9 serving as a pad electrode PAD is exposed. Note that the protective film PF may further include a polyimide film.

A member for external connection BW such as a bonding wire or a bump electrode is formed on a front surface of the pad electrode PAD, in step S7 to be described later.

As described above, a multilayer wiring layer having the metal film MF in the uppermost-layer wiring layer (ninth wiring layer WL9) is formed.

In addition, a processing history included in a manufacturing procedure of the semiconductor element 10 in step S2 and a manufacturing procedure of the multilayer wiring layer in step S3 are stored in a storage device MD.

In step S4, in each of the plurality of chip regions CHPa, a surface morphology image 1AI of a specific area 1A of the metal films MF is obtained.

As illustrated in FIG. 3, part of the metal films MF present in the chip region CHPa is provided as the specific area 1A. The position of the specific area 1A is the same for each of the plurality of chip regions CHPa. In the example of FIG. 3, as the specific area 1A, for example, part of the dummy pattern DP is used. As the specific area 1A, a portion of the wire M9 that is not used as a pad electrode PAD may be used. A planar size of the specific area 1A is, for example, 50 μm×50 μm or larger and 200 μm×200 μm or smaller.

As illustrated in FIG. 4, the surface morphology image 1AI of the specific area 1A is obtained for each of the plurality of chip regions CHPa, and these surface morphology images 1AI are stored in the storage device MD.

Note that, in step S4, it is desirable that the surface morphology image 1AI is obtained through the protective film PF, with the specific area 1A covered with the protective film PF. The surface morphology image 1AI is to be used in later timing, in matching with a surface morphology image 2AI of a semiconductor device 200 that has been determined to be defective. For example, when the specific area 1A is set in the pad electrode PAD, the member for external connection BW may be provided in the specific area 1A. In this case, the surface morphology image 2AI of the semiconductor device 200 cannot be obtained.

In addition, when the surface morphology image 2AI is obtained, if the specific area 1A is not covered with the protective film PF, a surface state of the specific area 1A of the semiconductor device 200 may be changed. In this case, obtaining an accurate surface morphology image 2AI becomes difficult.

In step S5, as illustrated in FIG. 4, the wafer identification number ID, pieces of positional information of the plurality of chip regions CHPa, positional information regarding the specific area 1A in each of the chip regions CHPa, and the surface morphology image 1AI for each of the plurality of chip regions CHPa are associated with one another and stored in the storage device MD. The surface morphology image 1AI associated with each piece of information in this manner can effectively be used for traceability of the semiconductor device 200 having been determined to be defective.

In step S6, the plurality of chip regions CHPa of the wafer WF are singulated into individual pieces along the dicing lines DL, so that the plurality of semiconductor chips CHP are obtained.

In step S7, the plurality of semiconductor chips CHP are sealed with a sealing resin SR, resulting in formation of the plurality of semiconductor devices 100.

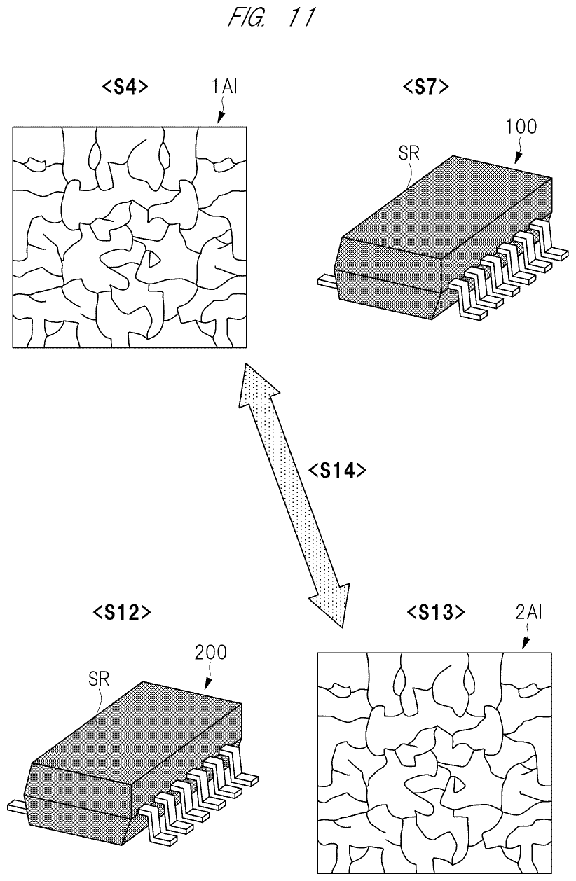

For example, first, the semiconductor chip CHP is mounted on a lead frame, and the member for external connection BW is used to allow each of the pad electrodes PAD to be electrically connected with a corresponding one of lead terminals. Then, the sealing resin SR such as epoxy resin is used to seal the semiconductor chip CHP and each of the lead terminals. Cutting off each of the lead terminals from the lead frame results in formation of the semiconductor device 100 illustrated in FIG. 11.

As described above, the plurality of semiconductor devices 100 can be obtained from the wafer WF.

In the first embodiment, in the course of manufacturing the semiconductor device 100 from the wafer WF, an in-line inspection, an electric characteristics test, and a screening test are conducted, and obtained pieces of inspection data or test data are used for identification of a defect of the semiconductor device 200 which will be described later.

In step S8, while steps S3 and S4 are performed, the in-line inspection is conducted appropriately. The in-line inspection includes any one or more of a foreign material inspection, a defect inspection, a dimensional inspection, an overlay inspection, and a visual inspection, for example.

In step S9, prior to step S6, the electric characteristics test is conducted on the semiconductor element 10 for each of the plurality of chip regions CHPa.

In step S10, prior to step S9, the screening test is conducted for screening reliability of each of the plurality of semiconductor devices 100. The screening test is, for example, a burn-in test.

Note that, as described above, the processing history included in the manufacturing procedure of the semiconductor element 10 in step S2 and the manufacturing procedure of the multilayer wiring layer in step S3 is stored in the storage device MD.

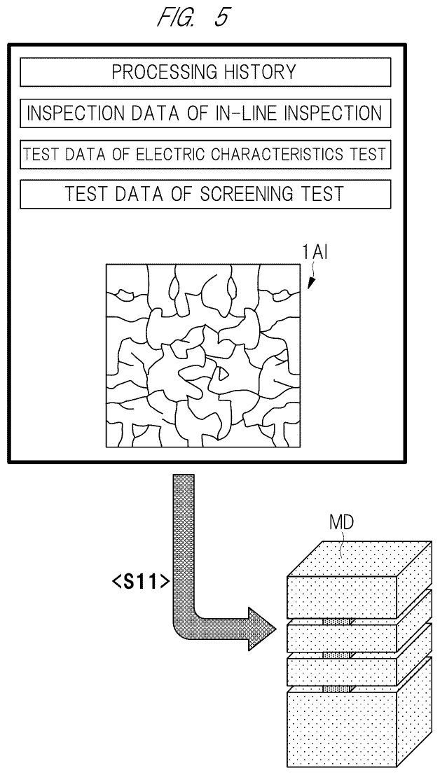

In step S11, as illustrated in FIG. 5, the processing history, the inspection data of the in-line inspection, the test data of the electric characteristics test, the test data of the screening test, and the surface morphology image 1AI of each of the plurality of chip regions CHPa are associated with one another and stored in the storage device MD.

For example, when the foreign material inspection is conducted as the in-line inspection, it is assumed that foreign material is detected in a certain chip region CHPa. At this point of time, the processing history is referred to, and the manufacturing condition of the manufacturing process in which the foreign material has been generated may be reviewed. However, all pieces of foreign material may not be led directly to a defect, and foreign material which may not be led to a defect even if the foreign material is left is also present. Hence, as long as there are no influences on the electric characteristics of the semiconductor element 10 and the reliability of the semiconductor device 100, it may be determined that such foreign material is allowed to be left as it is.

However, while the semiconductor device 100 is used, for some reason, the semiconductor device 100 becomes a defective product, and as a result of the failure analysis, there is also a possibility that foreign material that has been left may become a cause of the defect. As such, traceability is immediately performed on the semiconductor device 100 having a potential cause of the defect, and in order to identify the cause of the defect, the processing history, each inspection data, and each test data are preliminarily associated with the surface morphology image 1AI.

In step S12, as illustrated in FIG. 11, a semiconductor device 200 having been determined to be defective is obtained. The semiconductor device 200 having been determined to be defective is a semiconductor device that is returned, for example, due to some failure pointed out by a customer after being shipped as a product to the customer. In order to perform traceability of such a semiconductor device 200, the sealing resin SR of the semiconductor device 200 is opened. In addition, the member for external connection BW of the semiconductor device 200 is removed as needed.

In step S13, the surface morphology image 2AI of a portion corresponding to the specific area 1A of the metal films MF provided in the semiconductor device 200 is obtained. At this time, in a case in which the portion corresponding to the specific area 1A is covered with the protective film PF, the surface morphology image 2AI may be obtained in a state in which the protective film PF remains, or the surface morphology image 2AI may be obtained after the protective film PF is removed. Since the specific area 1A is protected by the protective film PF, even after the sealing resin SR is opened, the front surface of the specific area 1A is kept in a favorable state. Hence, the surface morphology image 2AI with higher accuracy can be obtained.

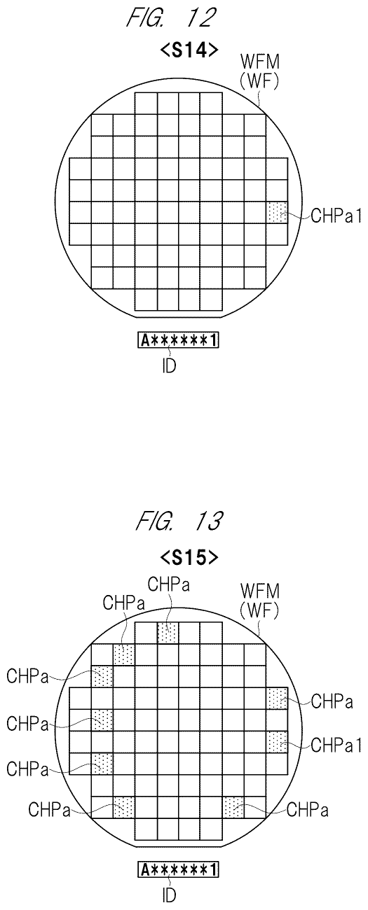

In step S14, as illustrated in FIG. 12, the surface morphology image 2AI is matched with the surface morphology image 1AI for each of the plurality of chip regions CHPa stored in the storage device MD, and accordingly, the wafer identification number ID of the wafer WF in which the semiconductor device 200 has been manufactured and the position of the chip region CHPa1 at which the semiconductor device 200 has been manufactured are identified.

Note that, in a case in which the surface morphology image 2AI does not match with any of the surface morphology images 1AI for the plurality of chip regions CHPa stored in the storage device MD, it can be identified that the semiconductor device 200 is a counterfeit product.

In step S15, the position of the chip region CHPa1 in which the semiconductor device 200 has been manufactured is identified, so that the processing history corresponding to the semiconductor device 200 can be identified, and any one or more of the inspection data of the in-line inspection, the test data of the electric characteristics test, and the test data of the screening test, in which each piece of data corresponds to the semiconductor device 200, can be identified.

For example, if the chip region CHPa1 in which the semiconductor device 200 has been manufactured is the chip region CHPa in which such foreign material that may be likely to cause no trouble even if it is left has been detected when the foreign material inspection has been conducted, it is possible to assume that the relevant foreign material may possibly be the cause of the defect.

In step S16, failure analysis is performed on the semiconductor device 200. The failure analysis includes any one or more of light emission analysis, OBIRCH (Optical Beam Induced Resistance Change) analysis, DLS (Dynamic Light Scattering) analysis, IDDQ (Quiescent Power supply Current) analysis, heat generating analysis, nanoprobing analysis, and EBAC (Electron Beam Absorbed Current) analysis.

In step S17, according to a relation between analysis data of the failure analysis and at least any one or more of the inspection data of the in-line inspection, the test data of the electric characteristics test, and the test data of the screening test, in which each piece of data corresponds to the semiconductor device 200, the cause of the defect of the semiconductor device 200 can be identified.

In step S15, if the inspection data of the in-line inspection, the test data of the electric characteristics test, and the test data of the screening test, in which each piece of data corresponds to the semiconductor device 200, are identified, a suitable analysis of the failure analyses to be performed in step S16 can preferentially be performed. For example, in a case in which the semiconductor device 200 has a history in which foreign material has been detected in the foreign material inspection and a history in which any abnormality has not been detected in a dimensional inspection, it can be expected that the detected foreign material is highly likely to cause the defect. Hence, a suitable failure analysis for detecting a defect that is to be expected can preferentially be performed.

In step S18, a result of step S17 is fed back to the method of manufacturing the semiconductor device 100. For example, the result of step S17 is fed back to steps S2 and S3, and reviewing of each of the manufacturing conditions is performed. For example, in a case in which it can be identified that the detected foreign material is the cause of the defect when the foreign material inspection is conducted as the in-line inspection, a countermeasure in which reviewing of a manufacturing process immediately before the foreign material is generated is performed in reference to the processing history can also be taken. Alternatively, another countermeasure in which commercialization of the chip region CHPa1 is not achieved, for example, is also taken.

In addition, as illustrated in FIG. 13, in step S15, another chip region CHPa having respective pieces of data similar to the inspection data of the in-line inspection, the test data of the electric characteristics test, and the test data of the screening test, in which each piece of data corresponds to the semiconductor device 200 (chip region CHPa1), may be present in some cases. In this case, as for the semiconductor device 100 manufactured from the relevant chip region CHPa, it can be estimated that the same defect as that of the semiconductor device 200 is highly likely to occur. Hence, on the wafer map WFM, the relevant chip region CHPa is subject to matching, and as for the relevant chip region CHPa, the same feedback as that in step S18 may also be performed.

In this manner, according to the first embodiment, it may not be required to allocate identification symbols to all of the semiconductor chips CHP, and there is no need to perform a special processing in the wafer WF, so that traceability can be achieved. Hence, cost increase in traceability can be reduced.

In addition, even after the sealing resin SR is opened and the member for external connection BW is removed, it is possible to obtain the accurate surface morphology image 2AI. More specifically, it is possible to obtain information leading to identification of the semiconductor chip CHP with higher accuracy. As such, it is possible to identify the cause of the defect of the semiconductor device 200 at an early stage, and early feedback to the method of manufacturing the semiconductor device 100 is achieved. Accordingly, after the feedback is performed, it is possible to supply the semiconductor device 100 having high reliability, improve the yield, and prevent a defective product from flowing out to the market.

### SECOND EMBODIMENT

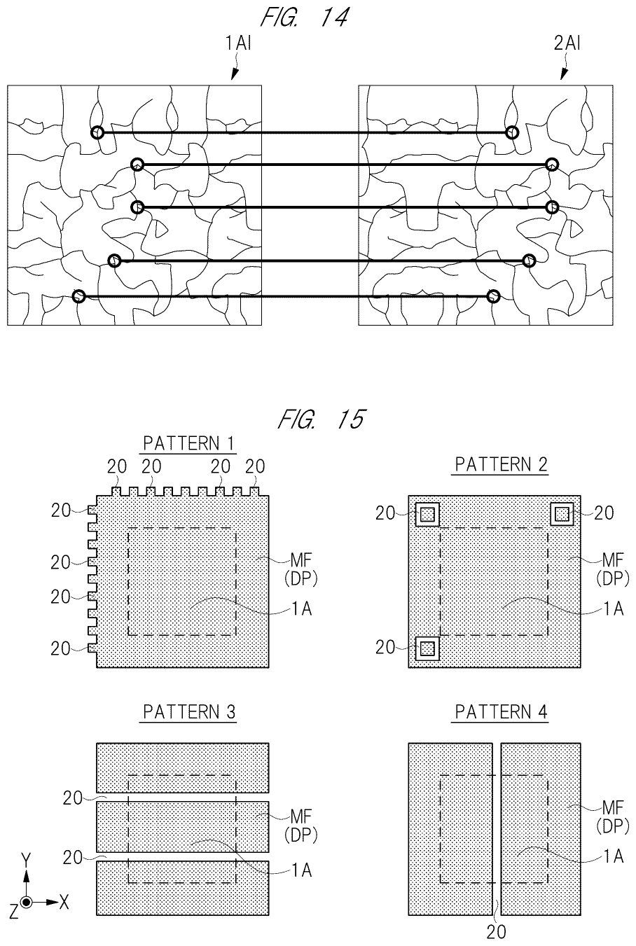

With reference to FIG. 14, the method of manufacturing the semiconductor device 100 and the product history management method of the semiconductor device 100 according to the second embodiment will be described below. Note that, in the following description, differences from the first embodiment are mainly described, and description regarding points overlapping with those in the first embodiment are omitted.

In the second embodiment, as illustrated in FIG. 14, for matching between the surface morphology image 1AI and the surface morphology image 2AI, a plurality of feature amounts extracted from respective images are used.

In step S4, the surface morphology image 1AI is obtained, and a plurality of feature amounts of the surface morphology image 1AI are extracted. For example, in the surface morphology image 1AI, an intersecting point at which a plurality of line segments meet together or a center of a region surrounded by the line segments is set as a feature point, and a feature amount at the feature point is extracted.

In step S5, a plurality of feature amounts are stored in the storage device MD as information relating to the surface morphology image 1AI.

In step S13, the surface morphology image 2AI is obtained, and a plurality of feature amounts of the surface morphology image 2AI are extracted.

In step S14, matching between the surface morphology image 2AI and the surface morphology image 1AI for each of the plurality of chip regions CHPa stored in the storage device MD is performed by comparing the plurality of feature amounts of the surface morphology image 2AI with the plurality of feature amounts of the surface morphology image 1AI.

In the second embodiment, the plurality of feature amounts of the respective surface morphology images are matched with each other, and if coordinates of the surface morphology image 1AI and the surface morphology image 2AI are not completely matched with each other, whether each of the images is an image in the specific area 1A can be determined.

For example, there may be a case in which coordinates when the surface morphology image 2AI is captured is slightly shifted from coordinates when the surface morphology image 1AI is captured, or a case in which the surface morphology image 2AI is captured in such a state as to be rotated relative to the surface morphology image 1AI. Even in such cases, if the plurality of feature amounts of the respective surface morphology images are matched with each other, it is possible to determine that these images are images in the specific area 1A. Hence, with use of the plurality of feature amounts of respective surface morphology images, it is possible to enhance the matching accuracy between the surface morphology image 1AI and the surface morphology image 2AI.

### THIRD EMBODIMENT

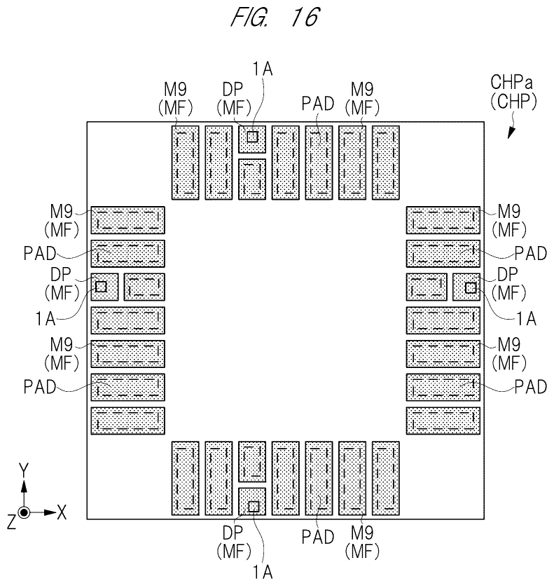

With reference to FIG. 15, the method of manufacturing the semiconductor device 100 and the product history management method of the semiconductor device 100 according to the third embodiment will be described. Note that, in the following description, differences from the first embodiment are mainly described, and points overlapping with those in the first embodiment are omitted.

In the third embodiment, as illustrated in FIG. 15, a geometric pattern 20 is provided in the metal film MF positioned in the specific area 1A or around the specific area 1A, or both in and around the specific area 1A. Note that, in FIG. 15, a region of the metal film MF surrounded by a broken line is indicated as the specific area 1A. In addition, in FIG. 15, a case in which the dummy pattern DP in a quadrangular shape is used as the metal film MF including the specific area 1A is illustrated as an example.

The geometric pattern 20 is provided, and accordingly, the specific area 1A can easily be found when the surface morphology image 1AI or the surface morphology image 2AI is obtained. Hence, accurate coordinates of the specific area 1A are easily matched, so that a matching accuracy of the surface morphology image 1AI and the surface morphology image 2AI can be enhanced. Note that shape data of the geometric pattern 20 is stored in the storage device MD as information relating to positional information of the specific area 1A in the chip region CHPa.

As the geometric pattern 20, “Pattern 1” to “Pattern 4” illustrated in FIG. 15 are illustrated as examples. In “Pattern 1,” as the geometric pattern 20, a plurality of protrusions and recesses are provided on at least one side of four sides of the metal film MF, in plan view. In “Pattern 2,” as the geometric pattern 20, three two-dimensional code patterns are provided in the metal film MF. In the case of “Pattern 2,” a region surrounded by three geometric patterns 20 can be recognized as the specific area 1A. In “Pattern 3” and “Pattern 4,” as the geometric pattern 20, a slit is provided in the metal film MF.

The geometric pattern 20 is not limited to shapes of “Pattern 1” to “Pattern 4,” and as long as it is a shape allowing the specific area 1A to be easily found, the geometric pattern 20 may be another pattern.

Note that the technique disclosed in the third embodiment can be applied in combination with the technique disclosed in the second embodiment.

### FOURTH EMBODIMENT

With reference to FIG. 16, the method of manufacturing the semiconductor device 100 and the product history management method of the semiconductor device 100 according to the fourth embodiment will be described below. Note that, in the following description, differences from the first embodiment are mainly described, and points overlapping with those in the first embodiment are omitted.

In the fourth embodiment, as illustrated in FIG. 16, a plurality of specific areas 1A are provided in the chip region CHPa. In step S4, in the plurality of chip regions CHPa, a surface morphology image 1AI is obtained for each of the plurality of specific areas 1A.

In step S13, a plurality of surface morphology images 2AI of portions corresponding to the plurality of specific areas 1A are obtained.

In step S14, the plurality of surface morphology images 2AI are matched with the plurality of surface morphology images 1AI for the plurality of chip regions CHPa stored in the storage device MD.

In a case in which a surface morphology image 1AI of only one specific area 1A for one chip region CHPa is obtained and a portion corresponding t to the specific area 1A of the semiconductor device 200 that has been determined to be defective is broken or deformed, obtaining the surface morphology image 2AI becomes difficult. For example, a stress applied from the sealing resin SR or the protective film PF may break or deform part of the metal film MF.

If the plurality of surface morphology images 1AI of the plurality of specific areas 1A are obtained for one chip region CHPa, even if obtaining the surface morphology image 2AI of a certain portion is difficult, it is sufficient if the surface morphology image 2AI of another portion may be obtained. Hence, according to the fourth embodiment, a risk that matching between the surface morphology image 1AI and the surface morphology image 2AI cannot be performed may easily be eliminated.

Note that the technique disclosed in the fourth embodiment can be applied in combination with the techniques disclosed in the second embodiment and the third embodiment.

In the foregoing, the present invention has been concretely described based on the embodiments. However, it is needless to say that the present invention is not limited to the foregoing embodiments and various modifications and alterations can be made within the scope of the present invention.

What is claimed is:

1. A method of manufacturing a semiconductor device, comprising:
(a) allocating a wafer identification number to a wafer including a semiconductor material;
(b) demarcating the wafer into a plurality of chip regions positioned in a matrix to generate a wafer map;
(c) forming a semiconductor element in each of the plurality of chip regions;
(d) forming a multilayer wiring layer positioned on an upper side of the semiconductor element in each of the plurality of chip regions and having a metal film in an uppermost-layer wiring layer thereof;
(e) obtaining a first surface morphology image of a specific area of the metal film in each of the plurality of chip regions; and
(f) associating the wafer identification number, positional information of each of the plurality of chip regions, positional information of the specific area in each of the chip regions, and the first surface morphology image for each of the plurality of chip regions with one another, and storing these pieces of information in the storage device.

2. The method of manufacturing a semiconductor device according to claim 1, wherein the metal film is a film containing aluminum as a main material.

3. The method of manufacturing a semiconductor device according to claim 1, wherein a member for external connection is not connected to the metal film.

4. The method of manufacturing a semiconductor device according to claim 1, wherein a planer size of the specific area is equal to or larger than 50 μm×50 μm and equal to or smaller than 200 μm×200 μm.

5. The method of manufacturing a semiconductor device according to claim 1,
wherein, in the (d), in such a manner as to cover the specific area, a protective film is formed on part of the metal film, and
wherein, in the (e), the first surface morphology image is obtained through the protective film.

6. The method of manufacturing a semiconductor device according to claim 1,
wherein, in the (e), a plurality of first feature amounts of the first surface morphology image are extracted, and
wherein, in the (f), the plurality of first feature amounts are stored in the storage device as information relating to the first surface morphology image.

7. The method of manufacturing a semiconductor device according to claim 1,
wherein a geometric pattern is provided in the metal film positioned in the specific area or around the specific area, or both in and around the specific area.

8. The method of manufacturing a semiconductor device according to claim 1,
wherein, in the (e), in each of the plurality of chip regions, a plurality of the respective first surface morphology images of a plurality of the specific areas are obtained.

9. The method of manufacturing a semiconductor device according to claim 1, further comprising:
(g) storing a processing history included in a manufacturing procedure of the semiconductor element included in the (c) and a manufacturing procedure of the multilayer wiring layer included in the (d) in the storage device;
(h) in the (c) and the (d), performing an in-line inspection; and
(i) associating the processing history, inspection data of the in-line inspection, and the first surface morphology image for each of the plurality of chip regions with one another, and storing these pieces of information in the storage device.

10. The method of manufacturing a semiconductor device according to claim 9,
wherein the in-line inspection includes any one or more of a foreign material inspection, a defect inspection, a dimensional inspection, an overlay inspection and visual inspection.

11. The method of manufacturing a semiconductor device according to claim 1, further comprising:
(j) performing an electric characteristics test on the semiconductor element for each of the plurality of chip regions; and
(k) associating test data of the electric characteristics test and the first surface morphology image for each of the plurality of chip regions with each other, and storing these pieces of information in the storage device.

12. The method of manufacturing a semiconductor device according to claim 1, further comprising:
(l) singulating the wafer into the plurality of chip regions, thereby obtaining a plurality of semiconductor chips;
(m) sealing each of the plurality of semiconductor chips with a sealing resin, thereby forming a plurality of first semiconductor devices;
(n) conducting a screening test for screening reliability of each of the plurality of first semiconductor devices; and
(o) associating test data of the screening test and a first surface morphology image for each of the plurality of chip regions with each other, and storing these pieces of information in the storage device.

13. A product history management method for a semiconductor device, comprising:
(a) allocating a wafer identification number to a wafer including a semiconductor material;
(b) demarcating the wafer into a plurality of chip regions positioned in a matrix to generate a wafer map;
(c) forming semiconductor element in each of the plurality of chip regions;
(d) forming a metal film in an uppermost-layer wiring layer of a multilayer wiring layer positioned on an upper side of the semiconductor element in each of the plurality of chip regions;
(e) obtaining a first surface morphology image of a specific area of the metal film in each of the plurality of chip regions;
(f) associating the wafer identification number, positional information of each of the plurality of chip regions, positional information of the specific area in each of the chip regions, and the first surface morphology image for each of the plurality of chip regions with one another, and storing these pieces of information in the storage device;
(g) singulating the wafer into the plurality of chip regions, thereby obtaining a plurality of semiconductor chips;
(h) sealing each of the plurality of semiconductor chips with a sealing resin, thereby forming a plurality of first semiconductor devices;
(i) obtaining a second semiconductor device which has been determined to be defective;
(j) opening the sealing resin of the second semiconductor device, and obtaining a second surface morphology image of a portion corresponding to the specific area of the metal film provided in the second semiconductor device; and
(k) matching the second surface morphology image with the first surface morphology image for each of the plurality of chip regions stored in the storage device, thereby identifying the wafer identification number of the wafer in which the second semiconductor device has been manufactured and a position of the chip region in which the second semiconductor device has been manufactured.

14. The product history management method for a semiconductor device according to claim 13, further comprising:
(l) storing a processing history included in a manufacturing procedure of the semiconductor element in the (c) and a manufacturing procedure of the multilayer wiring layer in the (d) in the storing device; and
(m) associating the processing history and the first surface morphology image for each of the plurality of chip regions with each other, and storing these pieces of information in the storage device,
wherein, in the (k), identifying the position of the chip region in which the second semiconductor device has been manufactured, thereby allowing history the processing corresponding to the second semiconductor device to be identified.

15. The product history management method for a semiconductor device according to claim 14, further comprising:
(n) during the (c) and the (d), conducting an in-line inspection;
(o) conducting an electric characteristics test on the semiconductor element;
(p) after the (h), conducting a screening test for screening reliability of each of the plurality of first semiconductor devices; and
(q) associating inspection data of the in-line inspection, test data of the electric characteristics test, test data of the screening test, and the first surface morphology image for each of the plurality of chip regions with one another, and storing these pieces of information in the storage device,
wherein, by identifying the position of the chip region in which the second semiconductor device has been manufactured in the (k), any one or more of the inspection data of the in-line inspection, the test data of the electric characteristics test, and the test data of the screening test, in which each piece of data corresponds to the second semiconductor device, is able to be identified.

16. The product history management method for a semiconductor device according to claim 15, further comprising:
(r) performing failure analysis on the second semiconductor device,
wherein, from a relation between analysis data of the failure analysis and any one or more of the inspection data of the in-line inspection, the test data of the electric characteristics test, and the test data of the screening test, in which each piece of data corresponds to the second semiconductor device, a cause of a defect of the second semiconductor device is able to be identified.

17. The product history management method for a semiconductor device according to claim 16,
wherein the failure analysis includes any one or more of light emission analysis, OBIRCH (Optical Beam Induced Resistance Change) analysis, DLS (Dynamic Light Scattering) analysis, IDDQ (Quiescent Power supply Current) analysis, heat generating analysis, nanoprobing analysis, and EBAC (Electron Beam Absorbed Current) analysis.

18. The product history management method for a semiconductor device according to claim 17,
wherein the identified cause of the defect of the second semiconductor device is fed back to the (c) and the (d).

19. The product history management method for a semiconductor device according to claim 13,
wherein, in a case in which the second surface morphology image does not match any of the first surface morphology images for the plurality of chip regions stored in the storage device, it is possible to identify that the second semiconductor device is a counterfeit product.

20. The product history management method for a semiconductor device according to claim 13,
wherein, in the (e), a plurality of first feature amounts of the first surface morphology image are extracted,
wherein, in the (g), the plurality of first feature amounts are stored in the storage device, as information relating to the first surface morphology image,
wherein, in the (j), a plurality of second feature amounts of the second surface morphology image are extracted, and
wherein, in the (k), matching of the second surface morphology image and the first surface morphology image for each of the plurality of chip regions stored in the storage device is performed by comparing the plurality of second feature amounts and the plurality of first feature amounts stored in the storage device.
